(19) United States
(12) Patent Application Publication
(10) Pub. No.: US 2014/0197512 A1
(43) Pub. Date: Jul. 17, 2014

(54) SEMICONDUCTOR DEVICE

(71) Applicant: ROHM CO., LTD., Kyoto-shi (JP)

(72) Inventor: Okimoto Kondo, Kyoto-shi (JP)

(73) Assignee: ROHM CO., LTD., Kyoto-shi (JP)

(21) Appl. No.: 14/149,031

(22) Filed: Jan. 7, 2014

(30) Foreign Application Priority Data
Jan. 15, 2013 (JP) 2013-004789
Nov. 22, 2013 (JP) 2013-242056

(51) Int. Cl. H01L 31/0203; H01L 31/02

(52) U.S. Cl. CPC H01L 31/0203; H01L 31/02002
USPC 257/433

(57) ABSTRACT

A semiconductor device includes a substrate with first and second lower electrodes, a semiconductor element supported on the substrate and including upper and lower electrodes, a conductive bonding material bonding the lower electrode of the element and the substrate to each other, a wire connecting the upper electrode of the element and the substrate to each other, and a sealing resin covering the semiconductor element and the wire. The substrate includes a barrier that encloses at least partially the conductive bonding material.

### BACKGROUND OF THE INVENTION

1. Field of the Invention

The present invention relates to a semiconductor device.

2. Description of the Related Art

As an example of a semiconductor device, a semiconductor device with a light-receiving element having a light-receiving surface is widely used. In the semiconductor device disclosed in JP-A-2007-12947, the light-receiving element is mounted on a substrate, with the light-receiving surface facing away from the substrate. The light-receiving element includes an element upper surface electrode and an element lower surface electrode which are provided on opposite sides. The element lower surface electrode is bonded to the substrate by e.g. a conductive bonding material. The element upper surface electrode is electrically connected to the substrate via a wire. The light-receiving element and the wire are covered by sealing resin. The sealing resin transmits light, such as infrared light, that is to be received by the light-receiving surface of the light-receiving element, and blocks visible light. The substrate has a first and a second substrate lower surface electrodes electrically connected to the element lower surface electrode and the element upper surface electrode. The semiconductor device can be surface-mounted by using the first and the second substrate lower surface electrodes.

To bond the light-receiving element to the substrate, the conductive bonding material in the form of a paste is applied to the substrate. Then, the light-receiving element is pressed against the conductive bonding material, and the conductive bonding material is hardened. In this way, the light-receiving element is bonded to the substrate. The conductive bonding material in the form of a paste easily spreads outward from the light-receiving element to the surrounding portions. Thus, the substrate needs to be large enough to cover the area to which the conductive bonding material is to spread. This makes the size of the semiconductor device considerably large, as compared with the size of the light-receiving element, or the size of the light-receiving surface, hindering size reduction of the semiconductor device, which is being demanded in accordance with size reduction of electronic equipment.

### SUMMARY OF THE INVENTION

The present invention has been conceived under the above-described circumstances. It is therefore an object of the present invention to provide a semiconductor device that can be reduced in size.

According to the present invention, there is provided a semiconductor device comprising: a substrate including a first substrate lower surface electrode and a second substrate lower surface electrode; a semiconductor element supported on the substrate and including an element upper surface electrode and an element lower surface electrode; a conductive bonding material bonding the element lower surface electrode and the substrate to each other; a wire connecting the element upper surface electrode and the substrate to each other; and a sealing resin covering the semiconductor element and the wire. The substrate includes a barrier that encloses at least partially the conductive bonding material.

In a preferred embodiment of the present invention, the substrate includes a recess which houses the semiconductor element and which includes a bottom surface and an inner side surface, and the barrier is provided by the inner side surface of the recess

In a preferred embodiment of the present invention, the substrate includes a first base providing the bottom surface of the recess, and a second base arranged on the first base and providing the side surface of the recess.

In a preferred embodiment of the present invention, the substrate includes a wire bonding pad which is formed on the second base and to which the wire is bonded.

In a preferred embodiment of the present. invention, the substrate includes a groove extending in a thickness direction of the substrate, and a groove conductive portion covering the groove and electrically connecting the wire bonding pad and the second substrate lower surface electrode to each other.

In a preferred embodiment of the present invention, the substrate includes a side surface conductive portion covering the inner side surface of the recess.

In a preferred embodiment of the present invention, the bottom surface of the recess is provided with a die bonding pad, and the semiconductor element is bonded to the die bonding pad by the conductive bonding material.

In a preferred embodiment of the present invention, the recess as viewed in plan and the semiconductor element as viewed in plan are similar in shape to each other.

In a preferred embodiment of the present invention, the substrate includes an element-side through-hole penetrating from the bottom surface of the recess to the first substrate lower surface electrode, and an element-side through-hole conductive portion covering the inner surface of the element-side. through-hole and electrically connecting the conductive bonding material and the first substrate lower surface electrode to each other.

In a preferred embodiment of the present invention, the element-side through-hole overlaps the semiconductor element as viewed in plan.

In a preferred embodiment of the present invention, the substrate includes an insulating resist film in the form of an enclosure as a whole as viewed in plan, and the barrier is provided by the inner edge of the insulating resist film.

In a preferred embodiment of the present invention, the substrate includes a wire bonding pad to which the wire is bonded.

In a preferred embodiment of the present invention, the substrate includes a wire-side through-hole penetrating from the wire bonding pad to the second substrate lower surface electrode, and a wire-side through-hole conductive portion covering the inner surface of the wire-side through-hole and electrically connecting the wire bonding pad and the second substrate lower surface electrode to each other.

In a preferred embodiment of the present invention, the wire-side through-hole overlaps the semiconductor element as viewed in plan.

In a preferred embodiment of the present invention, the insulating resist film covers a portion of the wire bonding pad.

In a preferred embodiment of the present invention, the portion of the wire bonding pad which is covered by the insulating resist film overlaps the semiconductor element as viewed in plan.

In a preferred embodiment of the present invention, the substrate is formed with a die bonding pad, and the semiconductor element is bonded to the die bonding pad by the conductive bonding material.

In a preferred embodiment of the present invention, the insulating resist film is provided at a position avoiding the die bonding pad.

In a preferred embodiment of the present invention, the insulating resist film covers the periphery of the die bonding pad.

In a preferred embodiment of the present invention, the die bonding pad includes a raised portion raised upward toward the semiconductor element in the thickness direction and provided in an area enclosed by the barrier.

In a preferred embodiment of the present invention, the raised portion is smaller in thickness than the insulating resist film.

In a preferred embodiment of the present invention, the die bonding pad includes a concavely curved edge.

In a preferred embodiment of the present invention, the insulating resist film includes an oblique portion inclined with respect to a side surface of the substrate. The substrate includes a corner positioned outside the oblique portion. The corner is in contact with the sealing resin.

In a preferred embodiment of the present invention, the substrate includes an element-side through-hole penetrating from the side formed with the insulating resist film toward the first substrate lower surface electrode, and an element-side through-hole conductive portion covering the inner surface of the element-side through-hole and electrically connecting the conductive bonding material and the first substrate lower surface electrode to each other.

In a preferred embodiment of the present invention, the element-side through-hole overlaps the semiconductor element as viewed in plan.

In a preferred embodiment of the present invention, the insulating resist film is in the form of a closed enclosure as a whole as viewed in plan.

In a preferred embodiment of the present invention, the insulating resist film comprises a plurality of regions.

In a preferred embodiment of the present invention, the semiconductor element is a light-receiving element including a light-receiving surface provided on the same side as the element upper surface electrode.

In a preferred embodiment of the present invention, the sealing resin transmits infrared light and blocks visible light

According to this structure, the barrier prevents the conductive bonding material from spreading excessively. Thus, it is not necessary to provide the substrate with an excess area in view of the spreading of the conductive bonding material. Thus, size reduction of the semiconductor device is achieved.

Other features and advantages of the present invention will become more apparent from detailed description given below with reference to the accompanying drawings.

### BRIEF DESCRIPTION OF THE DRAWINGS

FIG. 1 is a plan view of a semiconductor device according to a first embodiment of the present invention;

FIG. 2 is a plan view of a substrate of the semiconductor device of FIG. 1;

FIG. 3 is a bottom view of the semiconductor device of FIG. 1;

FIG. 4 is a sectional view taken. along lines IV-IV in FIG. 1;

FIG. 5 is a sectional view taken along lines V-V in FIG. 1;

FIG. 6 is a schematic sectional view taken along lines VI-VI in FIG. 1;

FIG. 7 is a plan view of a semiconductor device according to a second embodiment of the present invention;

FIG. 8 is a plan view of a substrate of the semiconductor device of FIG. 7;

FIG. 9 is a bottom view of the semiconductor device of FIG. 7;

FIG. 10 is a sectional view taken along lines X-X in FIG. 7;

FIG. 11 is a sectional view taken along lines XI-XI in FIG. 7;

FIG. 12 is a schematic sectional view taken along lines XII-XII in FIG. 7;

FIG. 13 is a plan view of a semiconductor device according to a third embodiment of the present invention;

FIG. 14 is a plan view of a substrate of the semiconductor device of FIG. 13;

FIG. 15 is a bottom view of the semiconductor device of FIG. 13;

FIG. 16 is a sectional view taken along lines XVI-XVI in FIG. 13;

FIG. 17 is a sectional view taken along lines XVII-XVII in FIG. 13;

FIG. 18 is a plan view of a semiconductor device according to a fourth embodiment of the present invention;

FIG. 19 is a sectional view of a semiconductor device according to a fifth embodiment of the present invention;

FIG. 20 is a. sectional view of a semiconductor device according to a sixth embodiment of the present invention;

FIG. 21 is a sectional view of a semiconductor device according to a seventh embodiment of the present invention;

FIG. 22 is a plan view of a semiconductor device according to an eighth embodiment of the present invention;

FIG. 23 is a plan view of a substrate of the semiconductor device of FIG. 22;

FIG. 24 is a bottom view of the semiconductor device of FIG. 22;

FIG. 25 is a sectional view taken along lines XXV-XXV in 22;

FIG. 26 is a plan view of a semiconductor device according to a ninth embodiment of the present invention;

FIG. 27 is a plan view of a substrate of the semiconductor device of FIG. 26;

FIG. 28 is a plan view of a semiconductor device according to a tenth embodiment of the present invention;

FIG. 29 is a plan view of a substrate of the semiconductor device of FIG. 26;

FIG. 30 is a sectional view taken along lines XXX-XXX in FIG. 28;

FIG. 31 is a plan view of a semiconductor device according to an eleventh embodiment of the present invention;

FIG. 32 is a plan view of a substrate of the semiconductor device of FIG. 31; and

FIG. 33 is a sectional view of a semiconductor device according to a twelfth embodiment of the present invention.

### DESCRIPTION OF THE PREFERRED EMBODIMENTS

Preferred embodiments of the present invention will be described below with reference to the accompanying drawings.

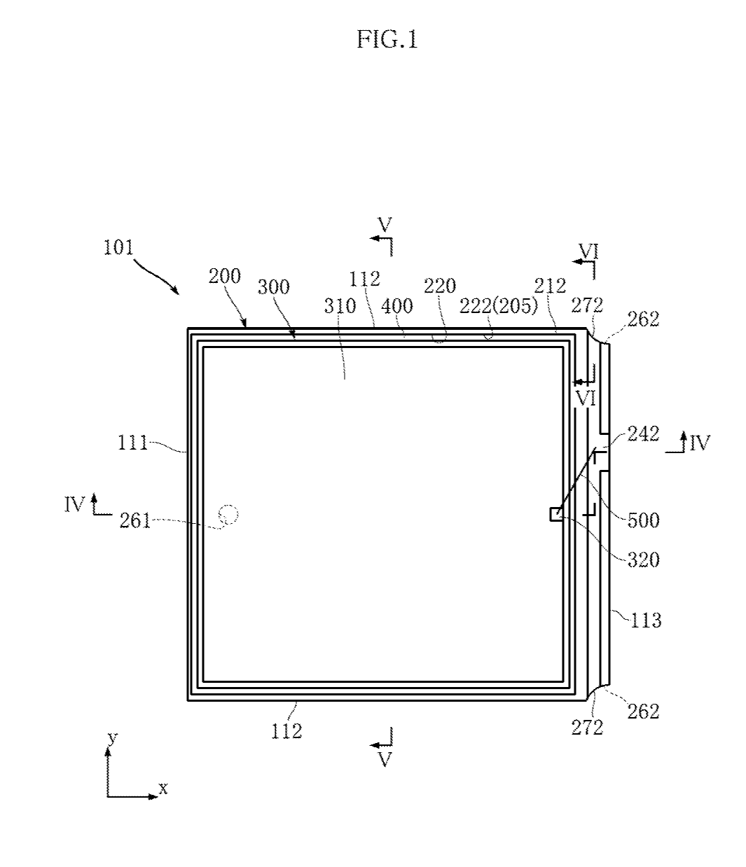

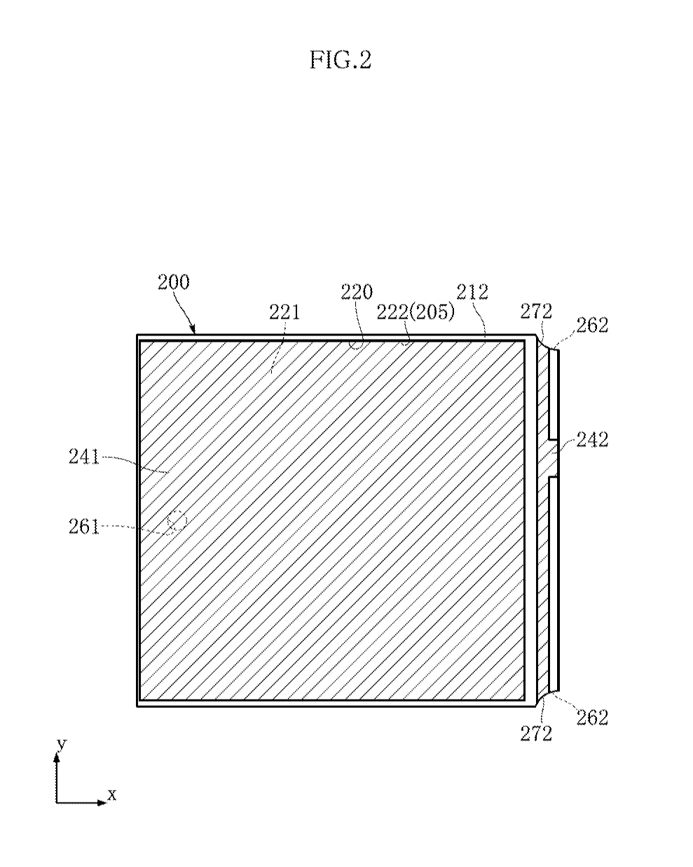

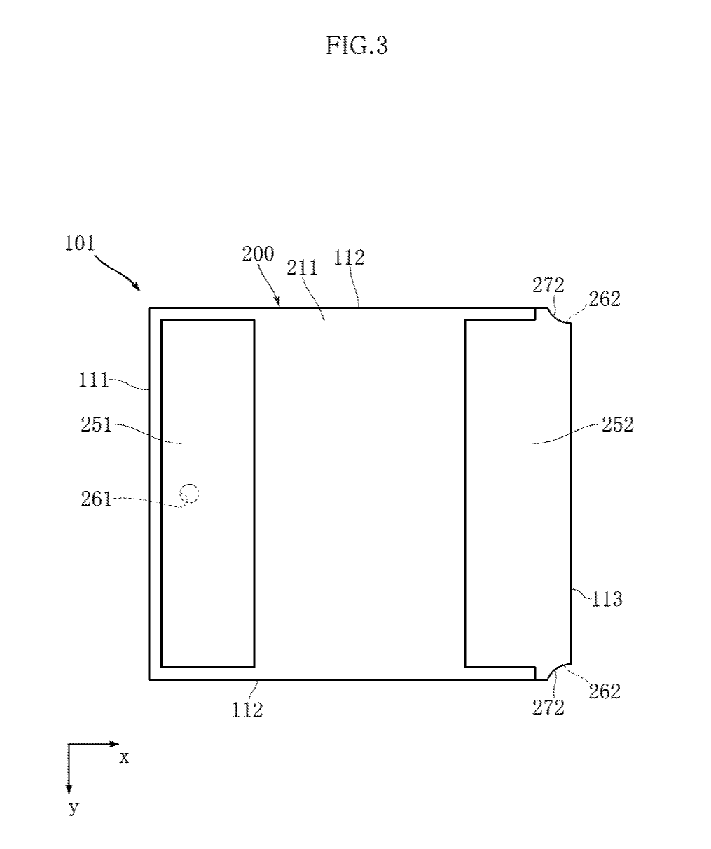

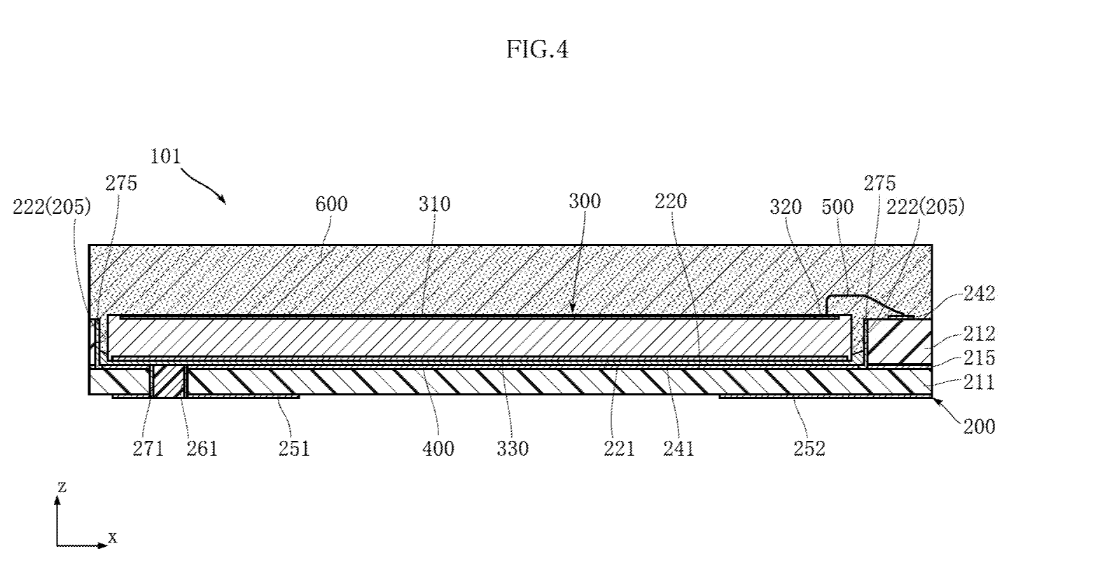

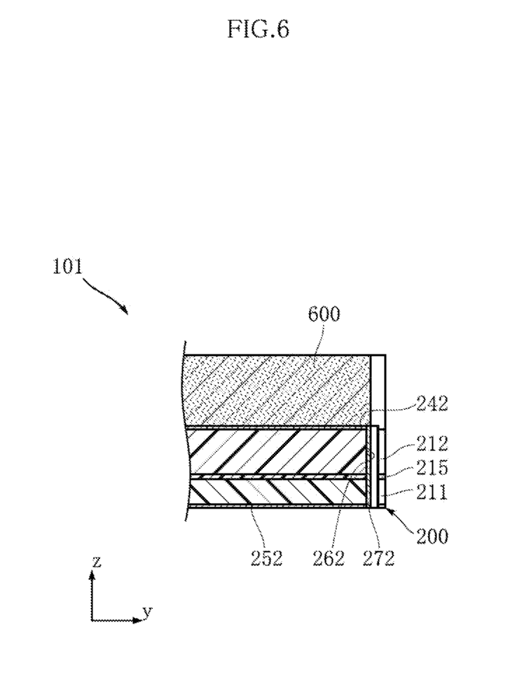

FIGS. 1-6 illustrate a semiconductor device according to a first embodiment of the present invention. The semiconductor device 101 of this embodiment includes a substrate 200 (see FIG. 4, for example), a semiconductor element 300, a conductive bonding material 400, a wire 500 and sealing resin 600 (not shown in FIG. 1). In this embodiment, the semiconductor device 101 is a light-receiving device configured to receive light and then output an electric signal corresponding to the brightness of the light received. FIG. 2 show a die bonding pad 241 and a wire bonding pad 212 (to be described later) indicated by hatching. For instance, the semiconductor device 101 has dimensions of about 3.4 mm in the direction x, about 3.0 mm in the direction y and about 0.7 mm in the direction z.

The substrate 200 supports the semiconductor element 300 and is provided with a signal path for outputting an electric signal from the semiconductor element 300.

The substrate 200 includes a first base 211 and a second base 212. The first base 211 and the second base 212 are made of an insulating material such as glass epoxy resin. The first base 211 is generally rectangular and about 0.1 mm in thickness. The second base 212 is arranged on the first base 211 and about 0.2 mm in thickness. The first base 211 and the second base 212 are bonded to each other by an adhesive sheet 215.

The lower surface of the substrate 200 is formed with a first substrate lower surface electrode 251 and a second substrate surface electrode 252. Each of the electrodes 251 and 252 is generally in the form of a rectangle elongated in the direction y. Each of the electrodes 251 and 252 comprises a lamination of a Cu layer and a flux layer or a lamination of a Cu layer, an Ni layer and an Au layer. For instance, the thickness of the Cu layer is about 10 μm, the thickness of the Ni layer is about 5 μm, and the thickness of the Au layer is about 0.2 μm.

The substrate 200 has a recess 220. The recess 220 is rectangular as viewed in plan. For instance, the recess 220 has dimensions of 3.1 mm in the direction x, 2.9 mm in the direction and 0.2 mm in depth in the direction z. In this embodiment, to provide the recess 220, a rectangular through-hole is formed in the second base 212.

The recess 220 has a bottom. surface 221 and a side surface 222 (in the illustrated example, the side surface 222 is made up of four flat faces, though the present invention is not limited to this). The bottom surface 221 is provided by the first base 211, and the side surface 222 is provided by the second base 212. The bottom surface 221 is formed with a die bonding pad 241. The die bonding pad 241 is rectangular as viewed in plan and slightly smaller than the bottom surface 221. The die bonding pad 241 may comprise a lamination of a Cu layer, an Ni layer and an Au layer. For instance, the thickness of the Cu layer is about 40 μm, the thickness of the Ni layer is about 5 μm, and the thickness of the Au layer is about 0.2 μm.

In this embodiment, the inner side surface 222 of the recess 220 constitutes a barrier 205 for providing a level difference. The barrier 205 is rectangular, as viewed in plan.

The side surface 222 is covered by a side surface conductive portion 275. In this embodiment, the side surface conductive portion 275 is connected to the die bonding pad 241. The side surface conductive portion 275 may comprise a lamination of a Cu layer, an Ni layer and an Au layer. For instance, the thickness of the Cu layer is about 40 μm, the thickness of the Ni layer is about 5 μm, and the thickness of the Au layer is about 0.2 μm.

The first base 211 is formed with an element-side through-hole 261. The element-side through-hole 261 penetrates the first base 211. As viewed in plan, the element-side through-hole 261 overlaps both of the die bonding pad 241 and the first substrate lower surface electrode 251. The inner surface of the element-side through-hole 261 is covered by an element-side through-hole conductive portion 271. The element-side through-hole conductive portion 271 is connected to both of the die bonding pad 241 and the first substrate lower surface electrode 251 to electrically connect the die bonding pad 241 and the first substrate lower surface electrode 251 to each other. For instance, the element-side through-hole conductive portion 271 comprises a lamination of a Cu layer, an Ni layer and an Au layer. For instance, the thickness of the Cu layer is about 40 μm, the thickness of the Ni layer is about 5 μm, and the thickness of the Au layer is about 0.2 μm.

The upper surface of the second base 212 in the direction z is formed with a wire bonding pad 242. The wire bonding pad 242 is provided at a position shifted from the recess 220 in the direction x. The wire bonding pad 242 is made up of a wider portion having a relatively large dimension in the direction x, and two strip portions extending from the wider portion in the direction y. The wire bonding pad 242 may comprise a lamination of a Cu layer, an Ni layer and an Au layer. For instance, the thickness of the Cu layer is about 40 μm, the thickness of the Ni layer is about 5 μm, and the thickness of the Au layer is about 0.2 μm .

Of the four corners of the substrate 200, two right corners in the direction x in FIG. 1 are formed with grooves 262, respectively. Each of the grooves 262 extends in the direction z along the entire thickness of the substrate 200 and is quarter-circular in cross section. Each groove 262 is covered by a groove conductive portion 272 The groove conductive portion 272 is connected to both of the wire bonding pad 242 and the second substrate lower surface electrode 252 to electrically connect the wire bonding pad 242 and the second substrate lower surface electrode 252 to each other. The groove conductive portion 272 may comprise a lamination of a Cu layer, an Ni layer and an Au layer. For instance, the thickness of the Cu layer is about 40 μm, the thickness of the Ni layer is about 5 μm, and the thickness of the Au layer is about 0.2 μm.

In this embodiment, the semiconductor element 300 is a light-receiving element having a photo-electric conversion function to output an electric signal corresponding to the brightness of the light received. The semiconductor element 300 includes a light-receiving surface 310, an element upper surface electrode 320 and an element lower surface electrode 330. The semiconductor element 300 has dimensions of about 3.0 mm in the direction x, about 2.8 mm in the direction y and about 0.2 mm in thickness in the direction z.

The light-receiving surface 310 is a surface for receiving light to be subjected to photo-electric conversion and occupies most part of the upper surface of the semiconductor element 300 in the direction z. For instance, the light-receiving surface 310 has dimensions of about 2.9 mm in the direction x and about 2.7 mm in the direction y. The element upper surface electrode 320 is provided on the same side as the light-receiving surface 310 at a position adjacent to the wire bonding pad 242 of the substrate 200. The element lower surface electrode 330 is provided on the lower surface of the semiconductor element 300 in the direction z and covers the lower surface entirely or partially.

Preferably, the proportion of the area of the light-receiving surface 310 to the area of the semiconductor device 101 as viewed in plan is in a range of 60 to 80% Preferably, the proportion of the area of the semiconductor element 300 to the area of the semiconductor device 101 as viewed in plan is in a range of 70 to 85%. Preferably, the proportion of the dimension in the direction x of the semiconductor device 101 to the dimension in the direction x of the light-receiving surface 310 is in a range of 85 to 95%. Preferably, referring to FIG. 1, the distance between the right edge of the light-receiving surface 310 in the direction x and the right edge of the semiconductor device 101 in the direction x is in a range of 5 to 15 of the dimension of the semiconductor device 101 in the direction x. The distance between the outer edge of the semiconductor element 300 and the outer edge of the semiconductor device 101 is smallest on the left side 111 in FIG. 1. in this embodiment, the smallest distance on the side 111 is not more than 0.1 mm. On each of the two sides 112 facing to the direction y, the distance between the outer edge of the semiconductor element 300 and the outer edge of the semiconductor device 101 is larger than the distance on the side 111. Preferably, the above-described distance on each side 112 is not more than 1.5 mm, and is 0.1 mm in this embodiment. The distance between the outer edge of the semiconductor element 300 and the outer edge of the semiconductor device 101 is largest on the right side 113 in FIG. 1. Preferably, the above-described distance on the side 113 is not more than 5.0 mm, and is 0.325 mm in this embodiment.

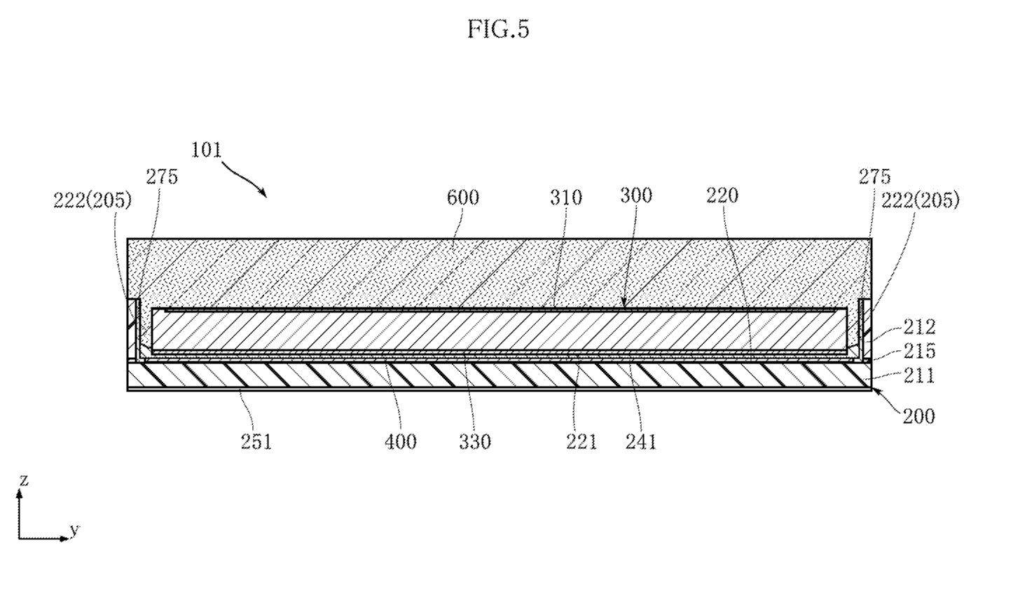

The conductive bonding material 400 bonds the semiconductor element 300 and the substrate 200 to each other, and in particular, bonds the element lower surface electrode 330 of the semiconductor element 300 and the die bonding pad 241 of the substrate 200 to each other. For instance, the conductive bonding material 400 is an epoxy resin mixed with Ag. As shown in FIGS. 4 and 5, in this embodiment, the conductive bonding material 400 spreads over the entire surface of each of the element lower surface electrode 330 and the die bonding pad 241 and is also provided in the space between the semiconductor element 300 and the side surface conductive portion 275.

In this embodiment, all of the conductive bonding material 400 is kept within the recess 220. That is, the conductive bonding material 400 is entirely enclosed by the barrier 205 provided by the side surface 222 of the recess 220.

One end of the wire 500 is bonded to the element upper surface electrode 320 of the semiconductor element. 300, and the other end of the wire 500 is bonded to the wire bonding pad 242 of the substrate 200. For instance, the wire 500 is made of Au.

The sealing resin 600 covers the semiconductor element 300 and the wire 500 for protection. In this embodiment, the sealing resin 500 transmits infrared light, which is to be received by the semiconductor element 300, while blocking visible light. In this embodiment, as shown in FIGS. 4 and 5, the sealing resin 600 covers the entirety of one side of the semiconductor device 101. The thickness of the sealing resin 600 in the direction z at the portion filling the recess 220 is about 0.6 mm.

The advantages of the semiconductor device 101 are described bed below.

According to this embodiment, the barrier 205 prevents the conductive bonding material 400 from spreading excessively. Thus, it is not necessary to provide the substrate 200 with an excess area in view of the spreading of the conductive bonding material 400. This leads to size reduction of the semiconductor device 101.

In this embodiment, the barrier 205 is provided by the side surface 222 of the recess 220 that is deep enough to accommodate the semiconductor element 300. Thus, the conductive bonding material 400 is reliably prevented from spreading beyond the barrier 205. Further, the depth of the recess 220 (hence the material-stopping effect of the barrier 205) can be increased simply by increasing the thickness of the second base 212 to be bonded to the first base 211.

As noted above, the side surface conductive portion 275 is electrically connected to the die bonding pad 241. Thus, when the conductive bonding material 400 is in contact with the side surface conductive portion 275, the resistance between the element lower surface electrode 330 of the semiconductor element 300 and the first substrate lower surface electrode 251 is reduced.

Providing the wire bonding pad 242 on the second base 212 reduces the height difference between the element upper surface electrode 320 of the semiconductor element 300 and the wire bonding pad 242 in the direction z. Thus, the length of the wire 500 can be reduced.

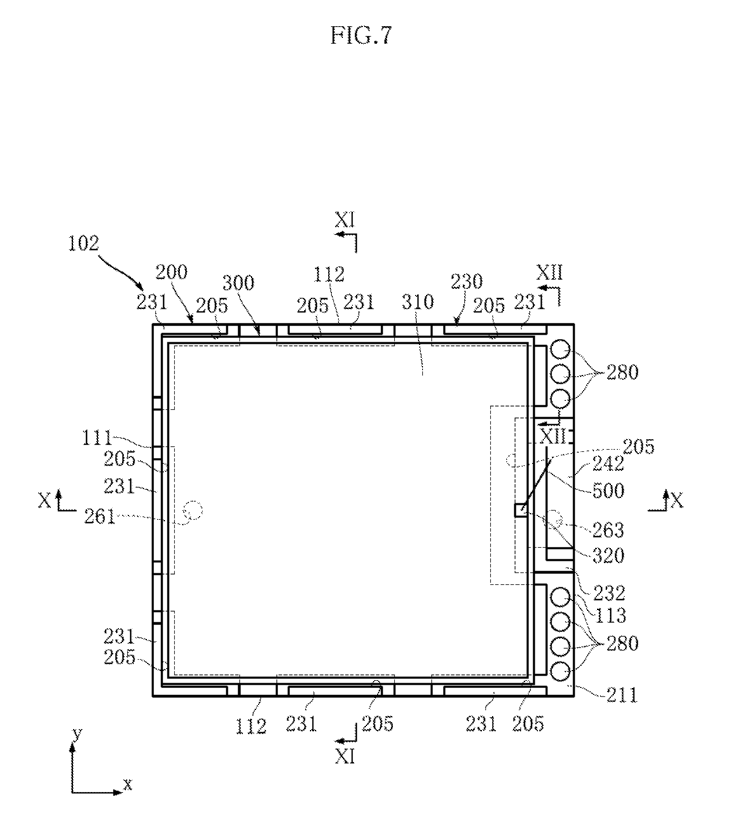

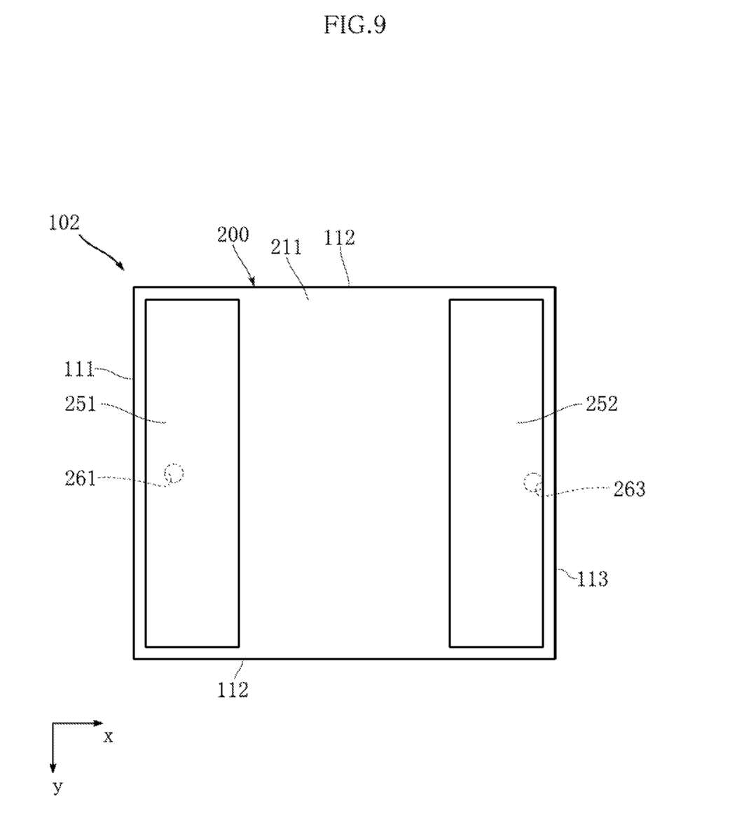

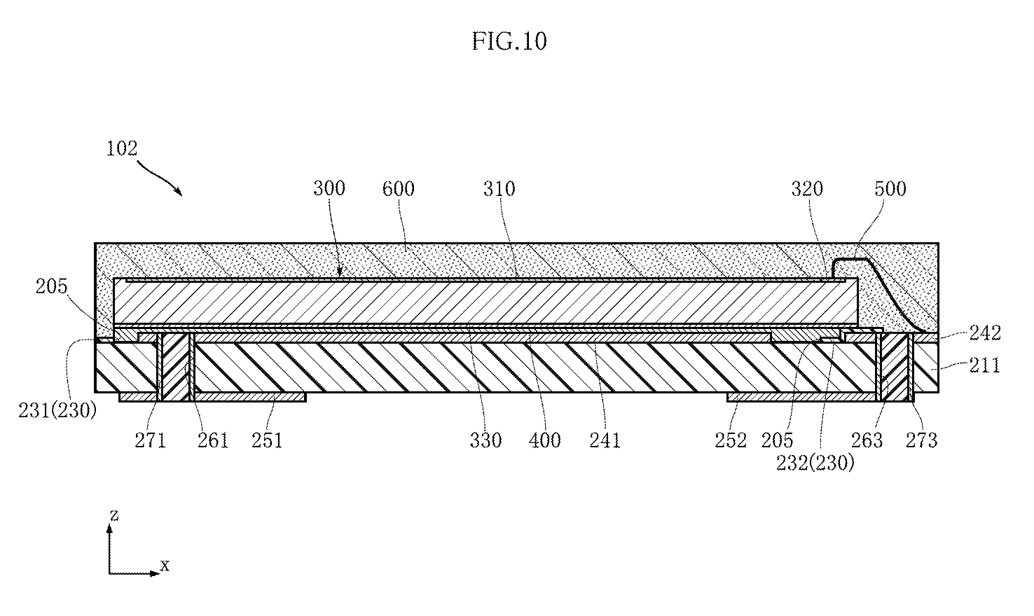

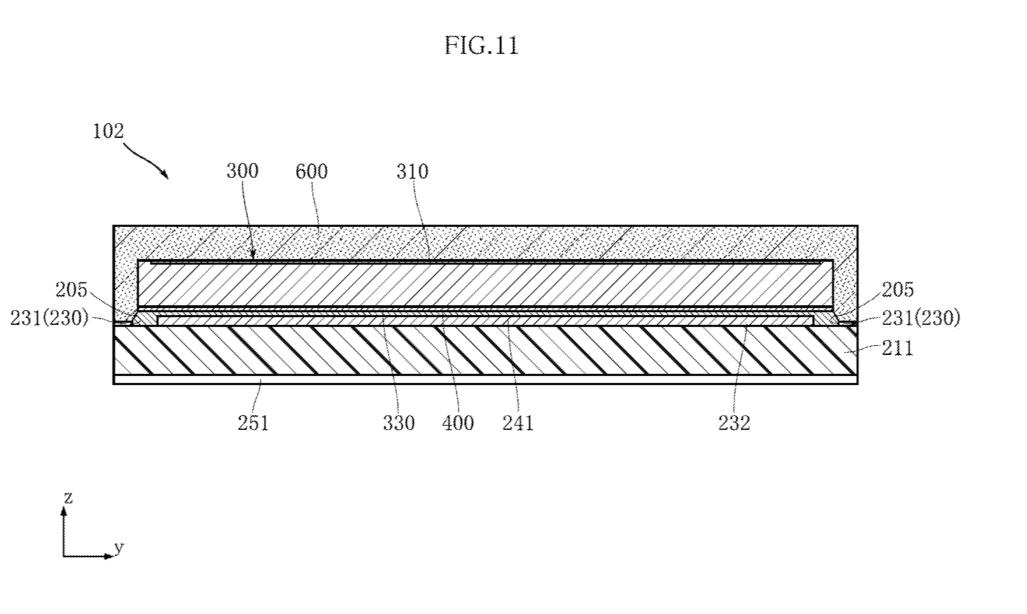

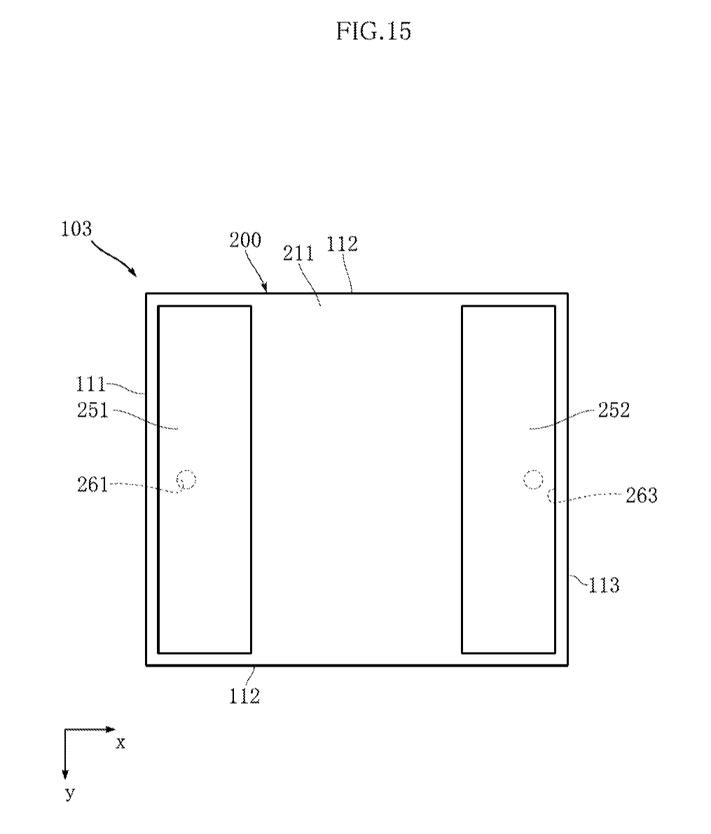

FIGS. 7-21 illustrate other embodiments of the present invention. In these figures, the elements that are identical or similar to those of the foregoing embodiment are designated by the same reference signs as those used for the foregoing embodiment.

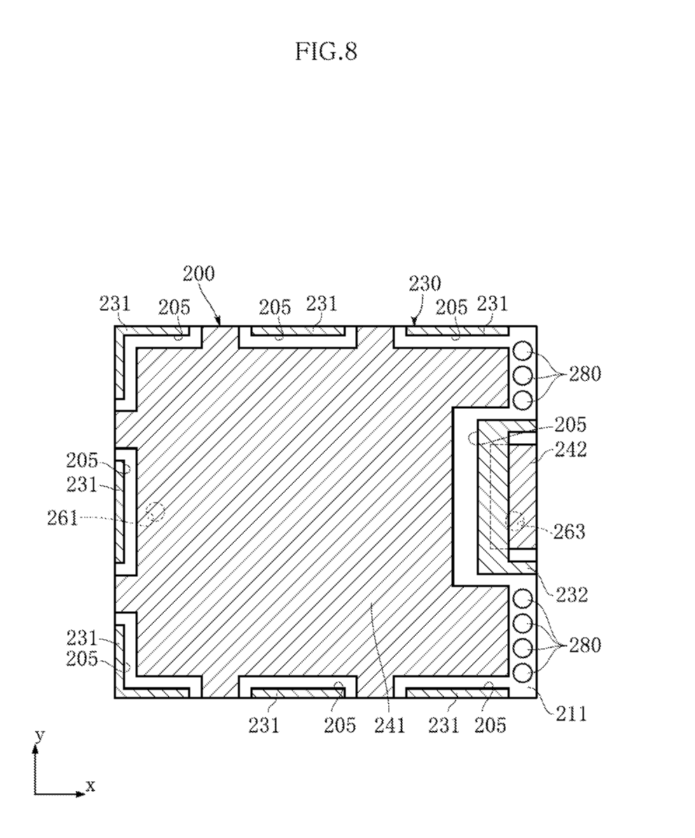

FIGS. 7-12 depict a semiconductor device 102 according to a second embodiment of the present invention. Like the semiconductor device 101 explained above, the semiconductor device 102 of the second embodiment includes a substrate 200, a semiconductor element 300, a conductive bonding material 400, a wire 500 and sealing resin 600 (not shown in FIG. 7). FIG. 8 shows a die bonding pad 241 and a wire bonding pad 242 indicated by diagonal hatching from lower left to upper right, while also showing an insulating resist film 230 (231, 232) indicated by diagonal hatching from lower right to upper left.

The semiconductor device 102 differs from the semiconductor device 101 mainly in structure of the substrate 200, and hence in bonding arrangement of the semiconductor element 300, as described later.

In the second embodiment, the substrate 200 includes a single base 211 that may correspond to the first base in the first. embodiment. As shown in FIG. 8, the die bonding pad 241 covers most part of the base 211. The die bonding pad 241, generally rectangular, is formed with a plurality of cutouts, including four rectangular cutouts (adjacent to the centers of the respective edges of the base 211) and four L-shaped cutouts at the respective corners of the base 211. In the illustrated example, the right-center rectangular cutout is greater in area than the other three rectangular cutouts. The wire bonding pad 242 is rectangular and much smaller in size than the die bonding pad 241. The wire bonding pad 242 is arranged adjacent to the right edge of the base 211 and at the center of the edge. A part of the wire bonding pad 242 is located in the relatively large, right-center cutout of the die bonding pad 241.

The base 211 is formed with a wire-side through-hole 263. The wire-side through-hole 263 penetrates the base 211. As viewed in plan, the wire-side through-hole 263 overlaps both of the wire bonding pad 242 and the second substrate lower surface electrode 252. The inner surface of the wire-side through-hole 263 is covered by a wire-side through-hole conductive portion 273. The wire-side through-hole conductive portion 273 is connected to both of the wire bonding pad 242 and the second substrate lower surface electrode 252 to electrically connect the wire bonding pad 242 and the second substrate lower surface electrode 252 to each other. The wire-side through-hole conductive portion 273 may comprise a lamination of a Cu layer, an Ni layer and an Au layer. For instance, the thickness of the Cu layer is about 40 μm, the thickness of the Ni layer is about 5 μm, and the thickness of the Au layer is about 0.2 μm.

In this embodiment, the substrate 200 has an insulating resist film 230. The insulating resist film 230 is made of an insulating resin and has a thickness of e.g. about 20 μm. As shown in FIG. 8, the insulating resist film 230 is made up of a plurality of regions 231, 232. The regions 231 are provided along the edges or at corners of the base 211 and received in the relatively small cutouts or L-shaped cutouts of the die bonding pad 241. The region 232 is generally U-shaped as viewed in plan and overlaps a part of the wire bonding pad 242. A part of the region 232 is located within the above-noted relatively large cutout of the die bonding pad 241. As shown in the figure, in this embodiment, the inner edges of the regions 231, 232 as a whole constitutes a barrier 205 that generally surrounds the die bonding pad 241.

According to this embodiment, where the barrier 205 is provided, the conductive bonding material 400 can be prevented from spreading beyond the barrier 205. On the other hand, where the barrier 205 is not provided (i.e., where the barrier 205 breaks off, thereby providing a gap), the conductive bonding material 400 may spread out through the gap. However, the spread-out amount of the bonding material 400 can be minimized e.g., by adjusting the number and/or positional relationship of the regions 231, 232. Hence, it is possible to prevent the conductive bonding material 400 from spreading unduly, even when the barrier 205 enclosed the bonding material 400 only partially.

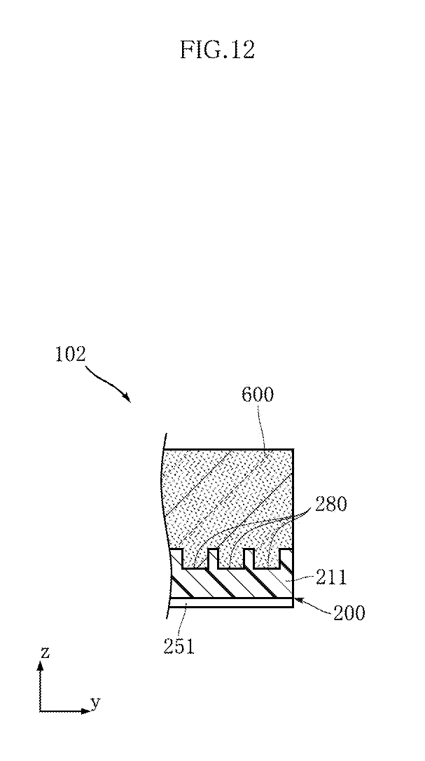

In this embodiment, the base 211 is formed with a plurality of anchor recesses 250. The anchor recesses 280 are provided in a region which is adjacent to the right edge in the direction x of the base 211 and in which the die bonding pad 241, the wire bonding pad 242 and the insulating resist film 230 are not provided. The anchor recesses 280 are aligned in the direction y. The anchor recesses 280 do not penetrate the base 211 and are formed b e.g. irradiating the base 211 with laser. As shown in FIG. 12, the anchor recesses 280 are filled with the sealing resin 600.

This arrangement also realizes size reduction of the semiconductor device 102. Formation of an insulating resist film is easy even when it has a relatively complicated shape. This makes it possible to select the shape of the insulating resist film 230 which reliably prevents spreading of the conductive bonding material 400 while also realizing proper bonding of the semiconductor element 300.

As noted above, the insulating resist film 230 of this embodiment is made up of a plurality of separate regions 231 and 232. Thus, when an excessive amount of conductive bonding material 400 is applied, the conductive bonding material 400 can be led to the outside through the gaps between the regions 231, 232. As a result, the semiconductor element 300 is prevented from leaning due to an excessive amount of conductive bonding material 400.

In the structure including the wire-side through-hole 263, the wire bonding pad 242 needs to be large enough to sufficiently overlap the wire-side through-hole 263. By covering a part of the wire bonding pad 242 by the region 232 of the insulating resist film 230, a part of the semiconductor element 300 and a part of the wire bonding pad 242 can overlap each other. This contributes to size reduction of the semiconductor device.

The anchor recesses 280 filled with the sealing resin 600 enhance the bonding strength of the substrate 200 and the sealing resin 600.

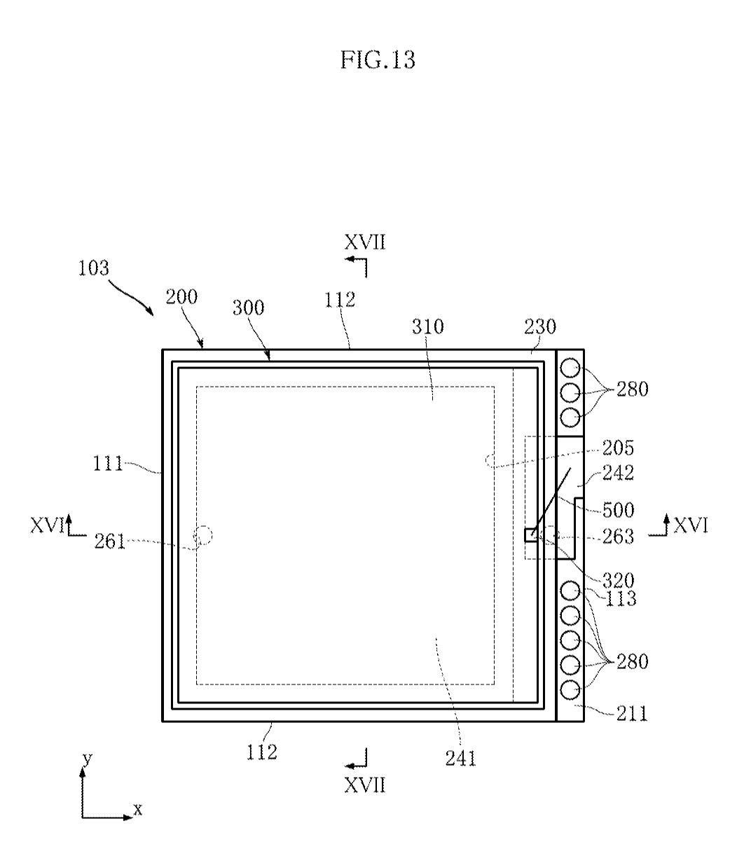

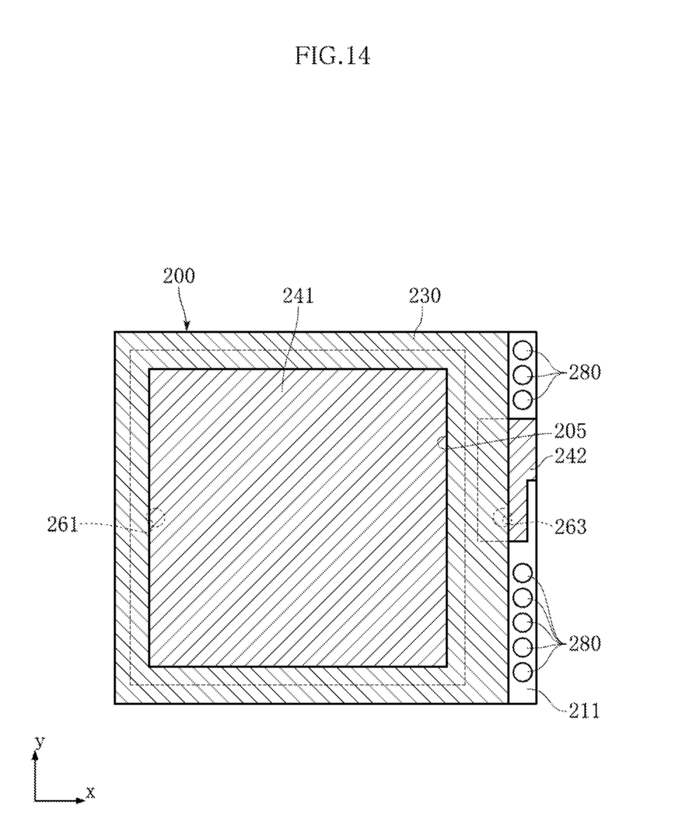

FIGS. 13-17 illustrate a semiconductor device 103 according to a third embodiment of the present invention. Like the previous semiconductor devices explained above, the semiconductor device 103 of the third embodiment includes a substrate 200, a semiconductor element 300, a conductive bonding material 400, a wire 500 and sealing resin 600 (not shown in FIG. 13) FIG. 14 shows a die bonding pad 241 and a wire bonding pad 242 indicated by diagonal hatching from lower left to upper right, while also showing an insulating resist film 230 indicated by diagonal hatching from lower right to upper left.

The semiconductor device 103 differs from the semiconductor devices 101, 102 mainly in structure of the substrate 200, and hence in bonding arrangement of the semiconductor element 300, as described later. As shown in FIG. 14, the die bonding pad 241 is rectangular.

The edges of the die bonding pad 241 are retreated (inwardly offset) from the edges of the base 211. In this embodiment, the insulating resist film 230 is in the form of a rectangular enclosure as viewed in plan, so that the barrier 205 is also in the form of a rectangular enclosure as viewed in plan. The periphery of die bonding pad 241 is covered by the insulating resist film 230. As shown in FIG. 13, the dimensions of the die bonding pad 241 are smaller than those of the semiconductor element 300 as viewed in plan, and therefore the die bonding pad 241 is within the semiconductor element 300 as viewed in plan.

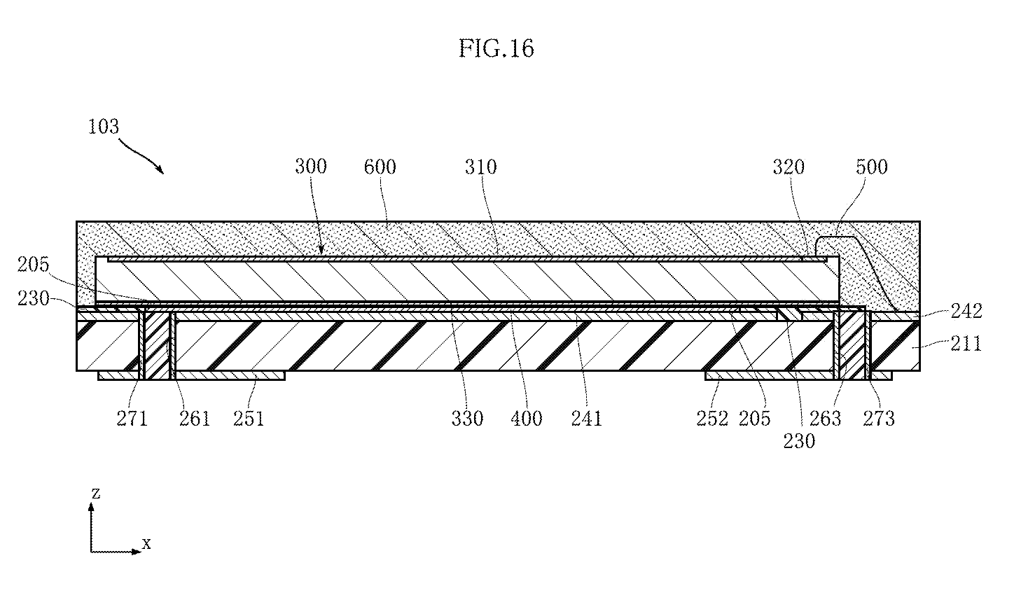

The wire bonding pad 242 is generally rectangular. The wire bonding pad 242 is covered by the insulating resist film 230 at a portion close to the die bonding pad 241. The portion of the wire bonding pad 242 which is covered by the insulating resist film 230 partially overlaps the semiconductor element 300 as viewed in plan. As viewed in plan, most part of the wire-side. through-hole 263 overlaps the insulating resist film 230. As shown in FIGS. 13 and 16, a part of the wire-side through-hole 263 overlaps the semiconductor element 300 as viewed in plan. In manufacturing the semiconductor device 103, part of the conductive bonding material 400 may spread onto the barrier 205, depending on the amount of the conductive bonding material 400 or the force with which the semiconductor element 300 is pressed. In this case, the conductive bonding material 400 enters between the insulating resist film 230 and the semiconductor element 300.

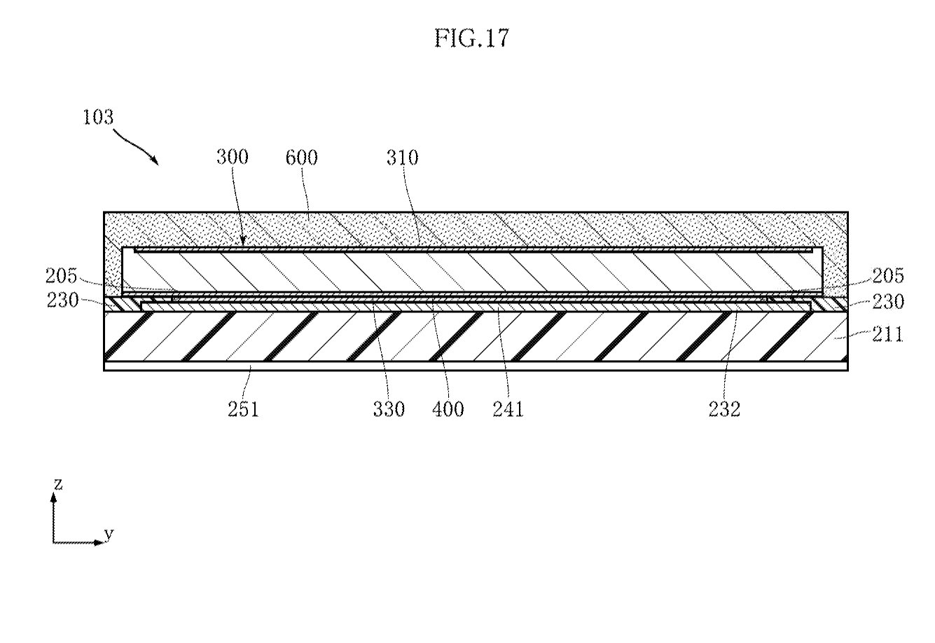

As shown in FIGS. 16 and 17, in this embodiment, the entirety of the conductive bonding material 400 is enclosed by the barrier 205.

In this embodiment again, size reduction of the semiconductor device is realized. Since the insulating resist film 230 supports the semiconductor element 300, the semiconductor element 300 is prevented from leaning.

The semiconductor element 300 and the wire-side through-hole 263 are arranged to overlap each other, with insulating resist film 230 positioned between them. This arrangement reduces the area of the wire bonding pad 242 which projects outward from the semiconductor element 300. This contributes to size reduction of the semiconductor device 103.

In this embodiment, the die bonding pad 241 is smaller than the semiconductor element 300. As viewed in plan, the barrier 205 is within the semiconductor element 300. This arrangement reliably keeps the conductive bonding material 400 within the region overlapping the semiconductor element 300. This contributes to size reduction of the semiconductor device 103.

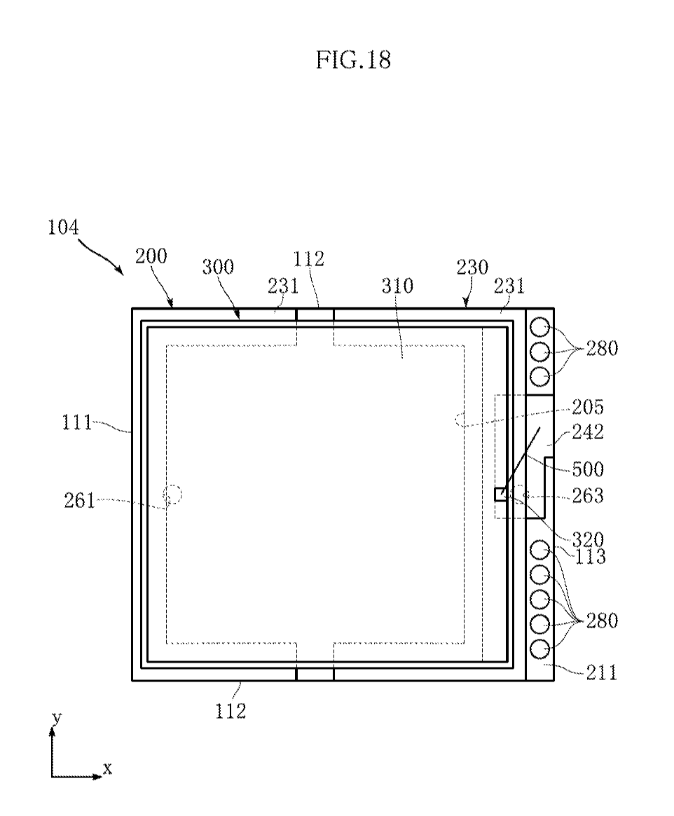

FIG. 18 illustrates a semiconductor device 104 according to a fourth embodiment of the present invention. The semiconductor device 104 of this embodiment differs from the semiconductor device 103 in structure of the insulating resist film 230. Like the pervious semiconductor devices, the device 104 of the fourth embodiment includes, among other things, sealing resin (reference sign 600 in the previous ones), though FIG. 18 does not depict it for simplicity of illustration.

In the fourth embodiment, the insulating resist film 230 is made up of two regions 231. The two regions 231 are separate from each other at the center of the base 211 in the direction x. Accordingly, the barrier 205, constituted by the two regions 231, is generally circular as a whole, but divided into two parts. This embodiment also realizes size reduction of the semiconductor device. It is expected that the excess of the conductive bonding material 400 can be led through the gaps between the two regions 231.

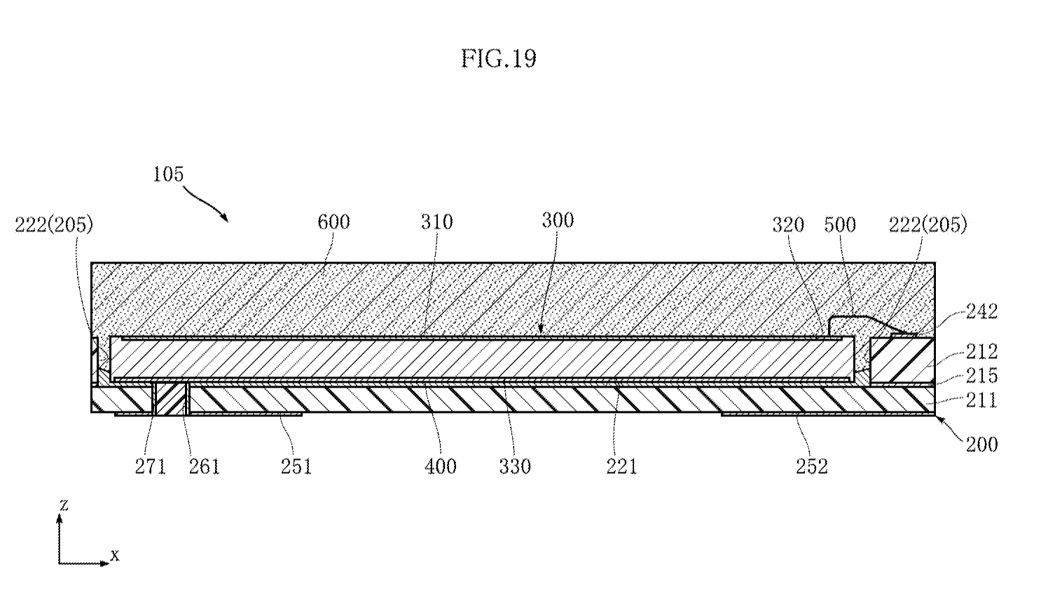

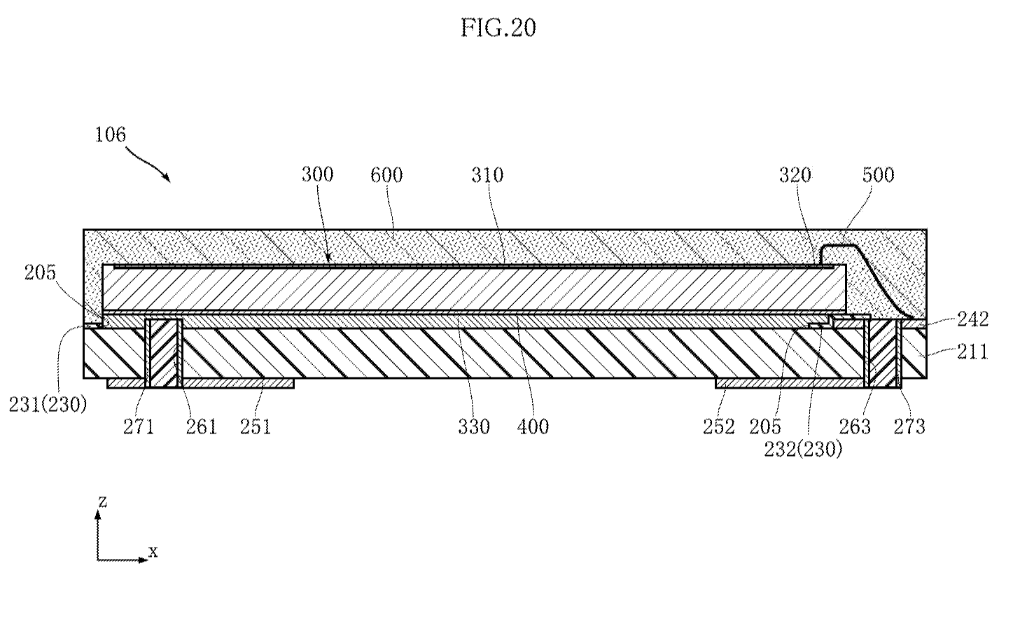

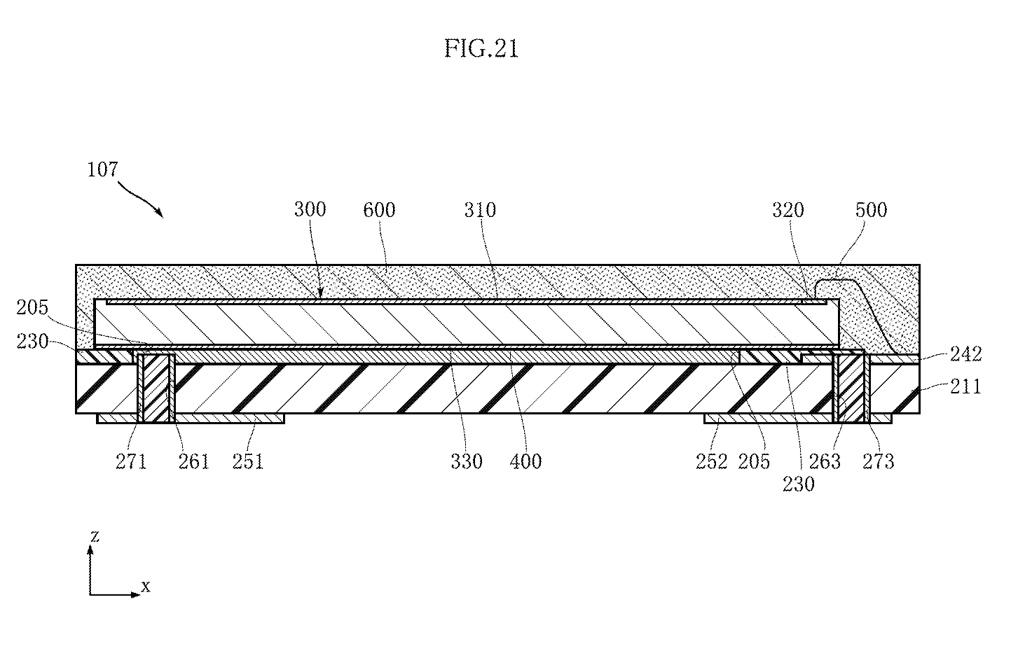

FIGS. 19-21 illustrate semiconductor devices 105, 106 and 107 according to fifth, sixth and seventh embodiments of the present invention, respectively. The semiconductor device 105 shown in FIG. 19 differs from the semiconductor device 101 in that the semiconductor device 105 does not include the die bonding pad 241 and the side surface conductive portion 275. The semiconductor device 106 shown in FIG. 20 differs from the semiconductor device 102 in that the semiconductor device 106 does not include the die bonding pad 241. The semiconductor device 107 shown in FIG. 21 differs from the semiconductor device 103 in that the semiconductor device 107 does not include the die bonding pad 241. In these embodiments, the element lower surface electrode 330 of the semiconductor element 300 is electrically connected to the element-side through-hole conductive portion 271 and hence to the first substrate lower surface electrode 251 by way of only the conductive bonding material 400. According to these embodiments again, size reduction of a semiconductor device is realized.

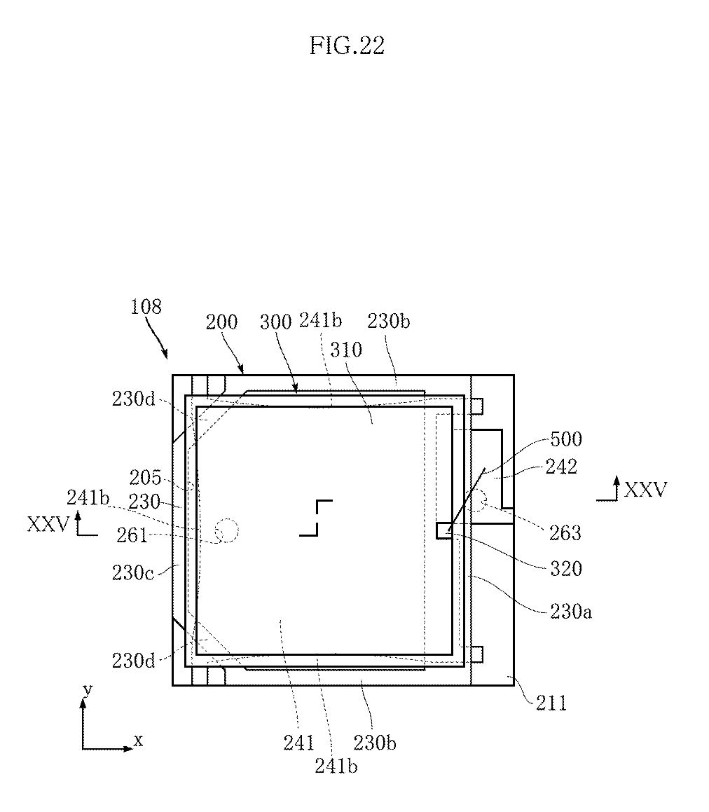

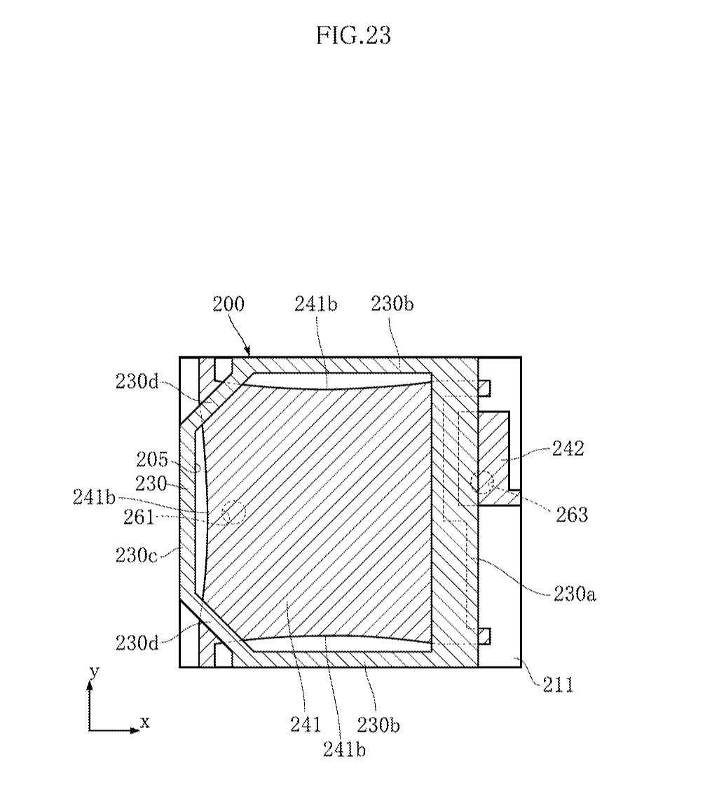

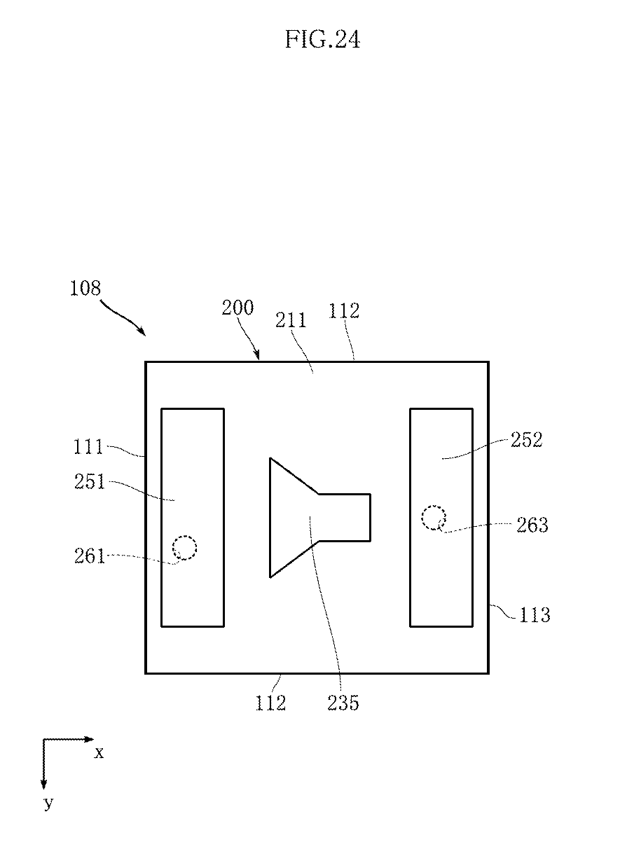

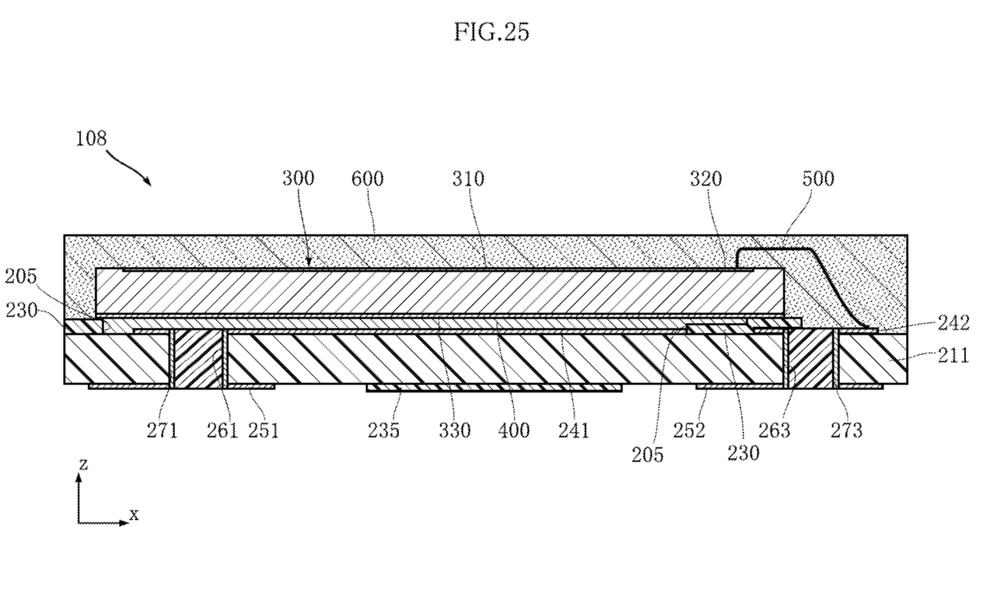

FIGS. 22-25 illustrate a semiconductor device 108 according to an eighth embodiment of the present invention. FIG. 22 is a plan view of the semiconductor device 108, FIG. 23 is a bottom. view of the semiconductor device 108, and FIG. 25 is a sectional view taken along lines XXV-XXV in FIG. 122. FIG. 24 is a plan view of the substrate 200. In FIG. 22, illustration of the sealing resin 600 is omitted for easier understanding. In FIG. 24, the die bonding pad 241 and the wire bonding pad 242 are indicated by hatching going diagonally from lower left to upper right, whereas the insulating resist film 230 is indicated by hatching going diagonally from lower right to upper left. The semiconductor device 103 of this embodiment differs from the semiconductor devices 101, 102 in structure of the substrate 200, and hence in bonding arrangement of the semiconductor element 300.

As shown in FIG. 23, the die bonding pad 241 has two strip portions each reaching an edge of the base 211. The die bonding pad 241 has three curved edges 241b. One of the three curved edges 241b is positioned on the opposite side of the wire bonding pad 242 in the direction x. The remaining two of the curved edges 241b are spaced apart from each other in the direction y. Each of these edges 241b is concavely curved as viewed in the direction z.

In this embodiment, the insulating resist film 230 is in the form of a closed, generally rectangular enclosure as viewed in plan, made up of an insulating covering portion 230a, two side edge portions 230b, an end edge portion 230c and two oblique portions 230d. Accordingly, the barrier 205 is also in the form of a closed, generally rectangular enclosure as viewed in plan. The insulating covering portion 230a overlaps both of the die bonding pad 241 and the wire bonding pad 242 and provides insulation particularly between the element lower surface electrode 330 of the semiconductor element 300 and the wire bonding pad 242. The two side edge portions 230b are formed along the two edges of the base 211 which are spaced apart from each other in the direction y. The end edge portion 230c is formed along an edge of the base 211 which is on the opposite side of the wire bonding pad 242 in the direction x. Each of the two oblique portions 230d is connected to one end of one of the side edge portions 230b and one end of the end edge portion 230c, and inclined with respect to both of the direction x and the direction y.

As shown in FIG. 22, the semiconductor element 300 overlaps at least part of the insulating covering portion 230a, at least part of the edge portion 230c and at least part of the two oblique portions 230d of the insulating resist film 230. However, the semiconductor element 300 does not overlap the two side edge portions 230b.

As shown in FIG. 25, in this embodiment, most part of the conductive bonding material 400 is enclosed by the barrier 205.

As shown in FIG. 24, the reverse surface of the base 211 of the substrate 200 is formed with a reverse surface insulating film 235. In the direction x, the reverse surface insulating film 235 is positioned between the first substrate lower surface electrode 251 and the second substrate lower surface electrode 252. The reverse surface insulating film 235 is provided to indicate the orientation of the semiconductor device 108.

According to this embodiment again, size reduction of the semiconductor device is realized.

Since the insulating resist film 230 includes two oblique portions 230d, the two corners of the base 211 of the substrate 200 are in contact with the sealing resin 600. The bonding strength between the base 211 and the sealing resin 600 is expected to be stronger than the bonding strength between the insulating resist film 230 and the sealing resin 600. Thus, this arrangement is advantageous for preventing separation of the substrate 200 and the sealing resin 600.

The curved edges 241b of the die bonding pad 241 and the base 211 provide a barrier corresponding to the thickness of the plating. The barrier can prevent the spreading of the conductive bonding material 400. Since the curved edges 241b are concave as viewed in plan, the conductive bonding material 400 can be kept at an inwardly shifted position. Thus, the spread of the conductive bonding material 400 is more reliably prevented.

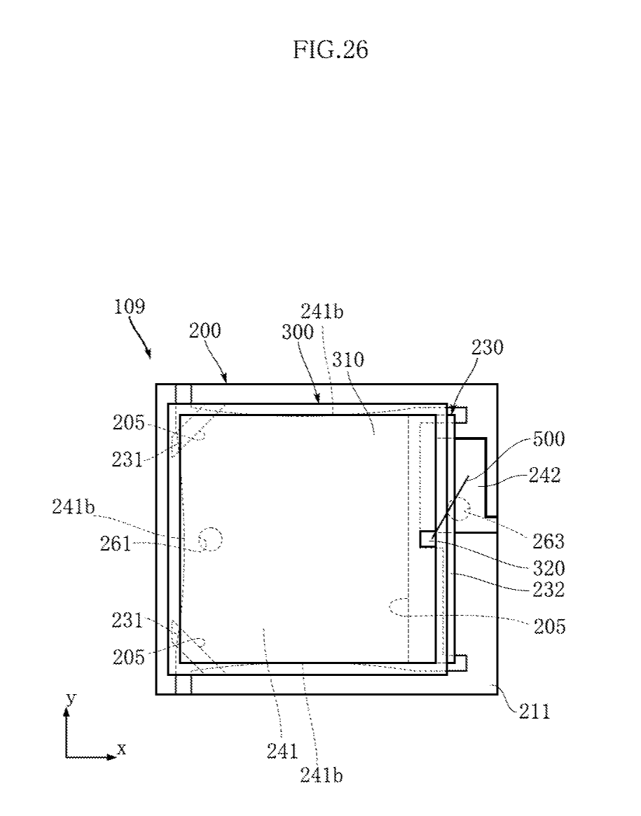

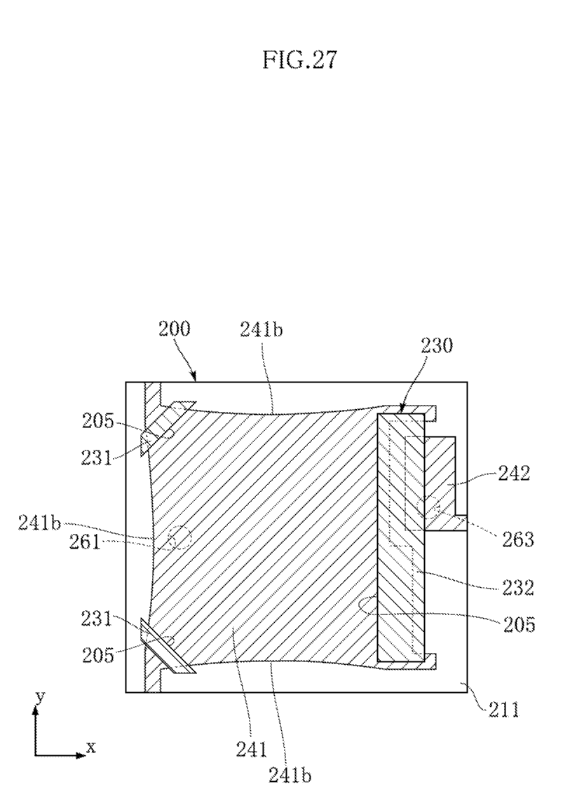

FIGS. 26 and 27 illustrate a semiconductor device 109 according to a ninth embodiment of the present invention. In the semiconductor device 109, the insulating resist film 230 includes a region 232 and two regions 231.

The region 232 corresponds to the insulating covering portion 230a of the semiconductor device 108. The two regions 231 correspond to the oblique portions 230d of the semiconductor device 108.

According to this embodiment again, size reduction of the semiconductor device is realized.

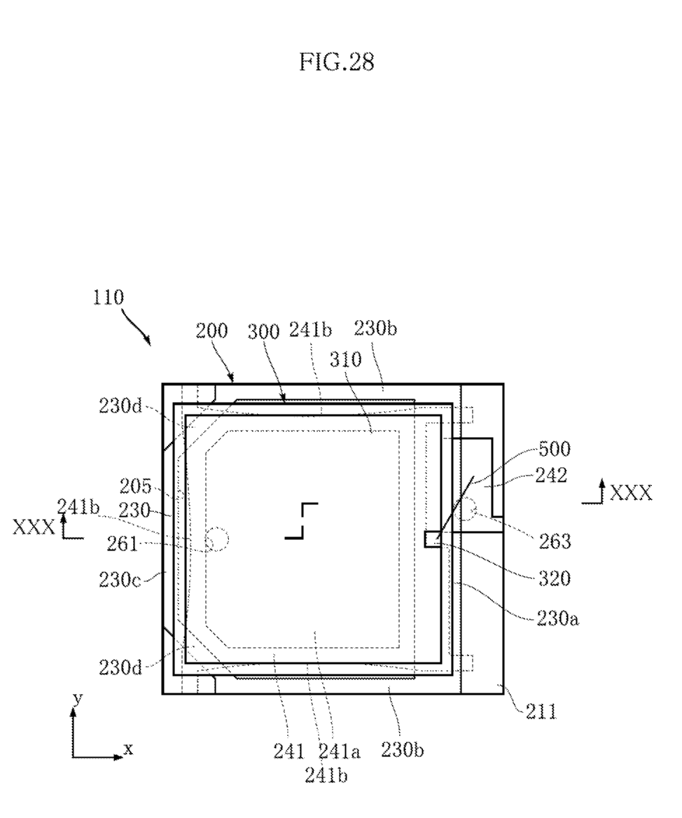

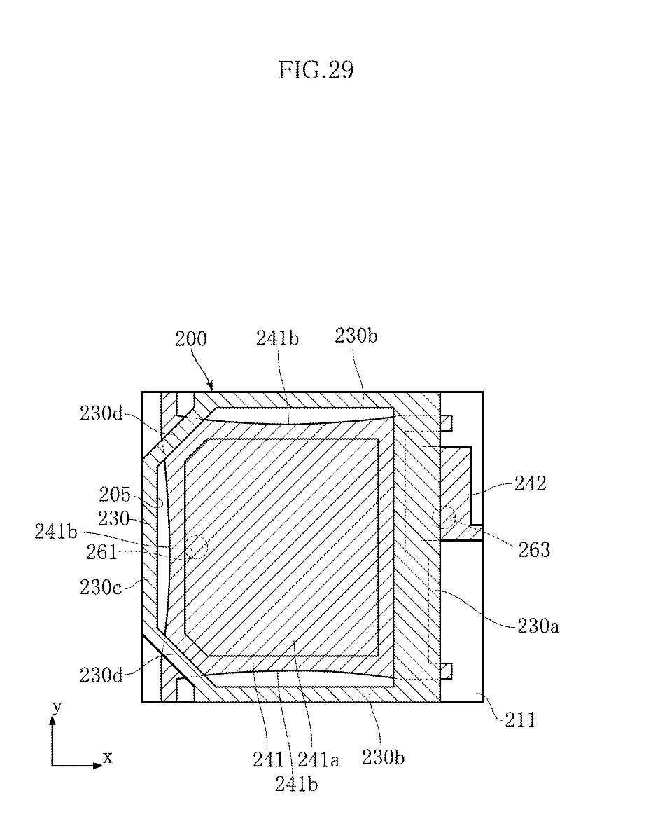

FIGS. 28-30 illustrate a semiconductor device 110 according to a tenth embodiment of the present invention. In the semiconductor device 110 of this embodiment, the die bonding pad 241 includes a raised portion 241a. The structures of other parts are substantially the same as those of the semiconductor device 108.

The raised portion 241a is a portion of the die bonding pad 241 which is raised upward in the direction z. The raised portion 241a is provided in the area surrounded by the insulating resist film 230. In this embodiment, the raised portion 241a has a shape corresponding to the shape of the barrier 205 provided by the insulating resist film 230 and is retreated inward from the barrier 205.

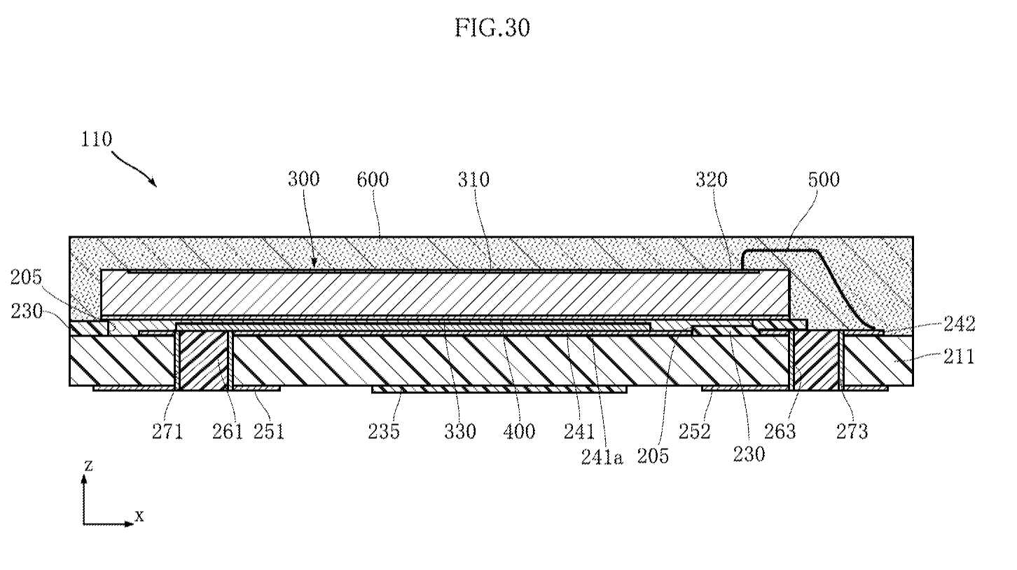

As shown in FIG. 30, the conductive bonding material 400 is present between the raised portion 241a of the die bonding pad 241 and the element lower surface electrode 330 of the semiconductor element 300. As compared with the insulating resist film 230 which is about 20 μm in thickness, the raised portion 241a is slightly thin and about 10-15 μm in thickness. Thus, in the state in which the element lower surface electrode 330 of the semiconductor element 300 is in contact with the insulating resist film 230, the conductive bonding material 400 can intervene between the element lower surface electrode 330 and the raised portion 241a. For instance, the raised portion 241a is formed by plating a part of the die bonding pad 241.

According to this embodiment again, size reduction of the semiconductor device is realized.

Owing to the presence of the raised portion 241a, no large gap is present between the element lower surface electrode 330 of the semiconductor element 300 and the die bonding pad 241. If a large gap is present between the element lower surface electrode 330 and the die bonding pad 241, the paste material to become the conductive bonding material 400 may not sufficiently come into contact with the element lower surface electrode 330, depending on the amount or viscosity of the paste material. In this embodiment, however, since the raised portion 241a is provided, the paste material is reliably sandwiched between the element lower surface electrode 330 and the raised portion 241a. Thus, the element lower surface electrode 330 and the die bonding pad 241 can be reliably bonded to each other by the conductive bonding material 400.

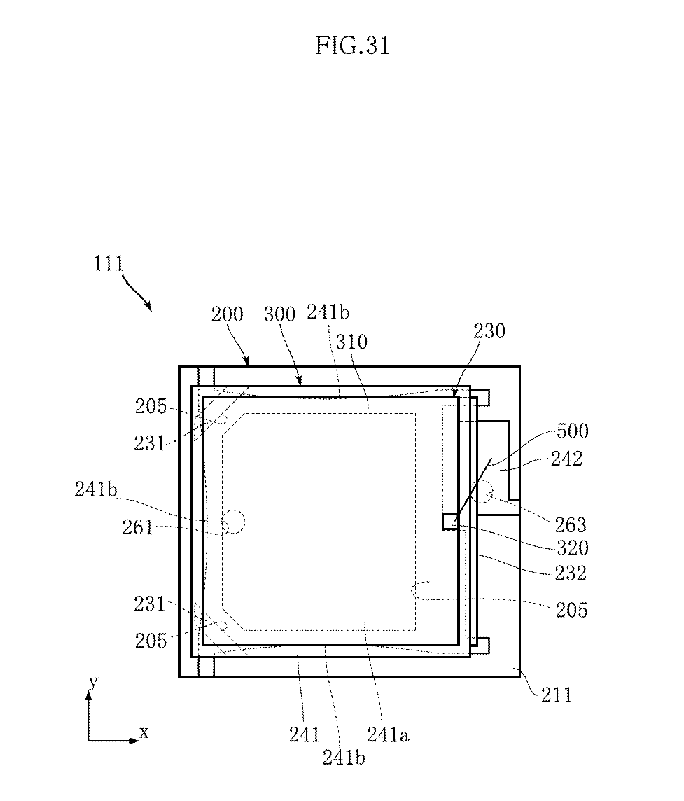

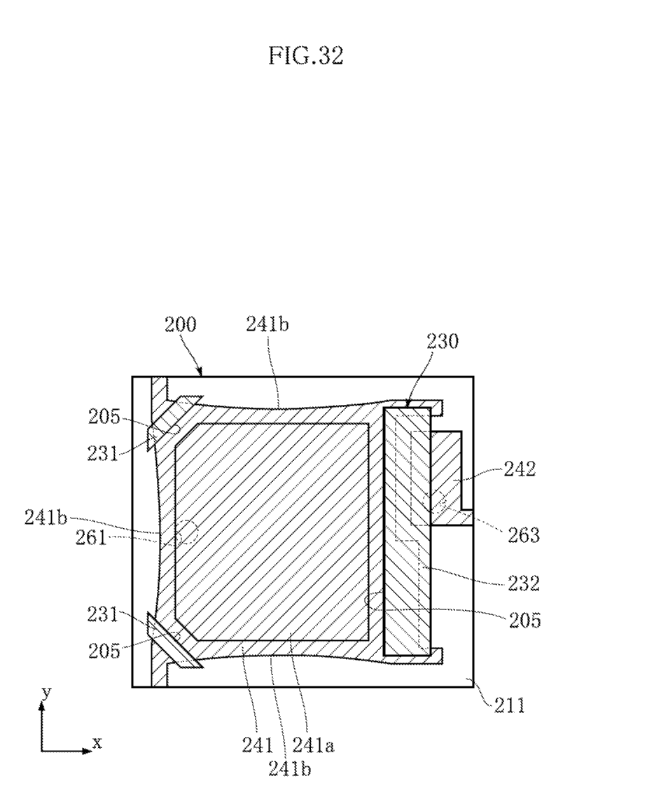

FIGS. 31 and 32 illustrate a semiconductor device 111 according to an eleventh embodiment of the present invention. The semiconductor device 111 of this embodiment has a structure obtained by providing the semiconductor device 109 with a raised portion similar to the raised portion 241a of the semiconductor device 110.

According to this embodiment again, size reduction of the semiconductor device is realized. Also, the element lower surface electrode 330 and the die bonding pad 241 can be reliably bonded to each other by the conductive bonding material 400.

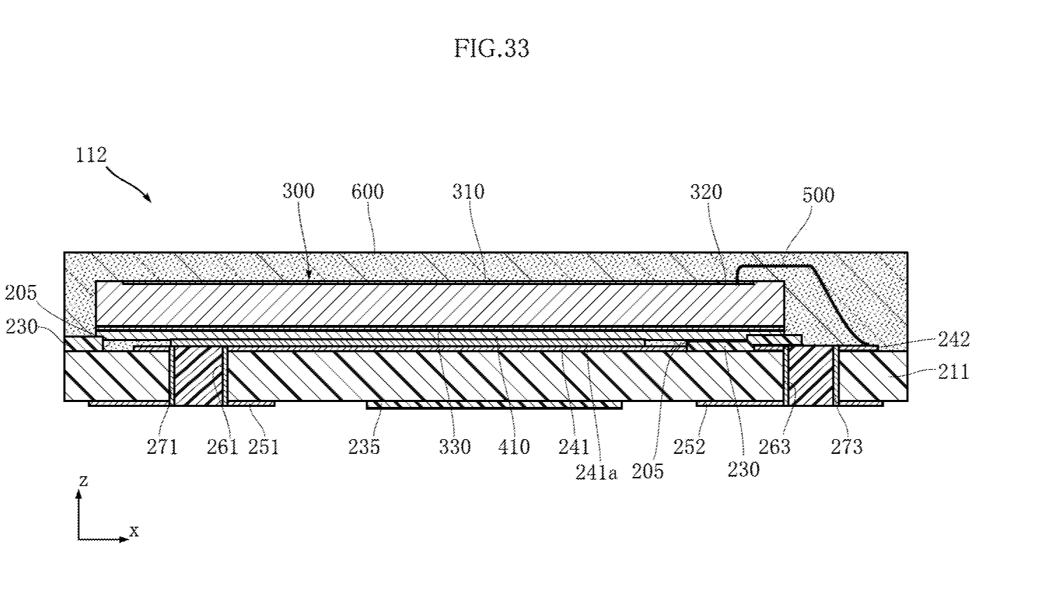

FIG. 33 illustrates a semiconductor device 112 according to a twelfth embodiment of the present invention. The semiconductor device 112 of this embodiment has a structure similar to that of the semiconductor device 110. In this embodiment, however, a conductive bonding sheet 410 is used to bond the element lower surface electrode 330 of the semiconductor element 300 and the die bonding pad 241 to each other, instead of the conductive bonding material 400.

The obverse and the reverse surfaces of the conductive: bonding sheet 410 are electrically connected to each other and have adhesive force. The conductive bonding sheet 410 is sandwiched between the element lower surface electrode 330 of the semiconductor element 300 and the raised portion 241a of the die bonding pad 241 to bond and electrically connect the element lower surface electrode 330 and the die bonding pad 241 to each other.

According to this embodiment again, size reduction of the semiconductor device is realized.

The semiconductor device according to the present invention is not limited to the foregoing embodiments. The specific structure of each part of the semiconductor device according to the present invention may be varied in design in many ways.

The semiconductor element of the semiconductor device of the present invention is not limited to a light-receiving element, and various kinds of semiconductor elements such as a semiconductor light-emitting element, a transistor or a diode can be employed.

1. A semiconductor device comprising:
a substrate including a first substrate lower surface electrode and a second substrate lower surface electrode;
a semiconductor element supported on the substrate, the semiconductor element including an element upper surface electrode and an element lower surface electrode;
a conductive bonding material bonding the element lower surface electrode and the substrate to each other;
a wire connecting the element upper surface electrode and the substrate to each other; and
a sealing resin covering the semiconductor element and the wire;
wherein the substrate includes a barrier that encloses at least partially the conductive bonding material.

2. The semiconductor device according to claim 1, wherein the substrate includes a recess that houses the semiconductor element, the recess including a bottom surface and an inner side surface, and
the barrier is provided by the inner side surface of the recess.

3. The semiconductor device according to claim 2, wherein the substrate includes a first base and a second base, the first base providing the bottom surface of the recess, the second base being arranged on the first base and providing the inner side surface of the recess.

4. The semiconductor device according to claim 3, wherein the substrate includes a wire bonding pad to which the wire is bonded, the wire bonding pad being formed on the second base.

5. The semiconductor device according to claim 4, wherein the substrate includes a groove extending in a thickness direction of the substrate and a groove conductive portion covering the groove, the groove conductive portion electrically connecting the wire bonding pad and the second substrate lower surface electrode to each other.

6. The semiconductor device according to claim 2, wherein the substrate includes a side surface conductive portion covering the inner side surface of the recess.

7. The semiconductor device according to claim 2, wherein the bottom surface of the recess is provided with a die bonding pad, the semiconductor element being bonded to the die bonding pad by the conductive bonding material.

8. The semiconductor device according to claim 2, wherein the recess as viewed in plan and the semiconductor element as viewed in plan are similar in shape to each other.

9. The semiconductor device according to claim 2, wherein the substrate includes an element-side through-hole penetrating from the bottom surface of the recess to the first substrate lower surface electrode, and an element-side through hole conductive portion covering an inner surface of the element-side through-hole and electrically connecting the conductive bonding material and the first substrate lower surface electrode to each other.

10. The semiconductor device according to claim 9, wherein the element-side through-hole overlaps the semiconductor element as viewed in plan.

11. The semiconductor device according to claim 1, wherein the substrate includes an insulating resist film in a form of an enclosure as a whole as viewed in plan, and
the barrier is provided by an inner edge of the insulating resist film.

12. The semiconductor device according to claim 11, wherein the substrate includes a wire bonding pad to which the wire is bonded.

13. The semiconductor device according to claim 12, wherein the substrate includes a wire-side through-hole penetrating from the wire bonding pad to the second substrate lower surface electrode, and a wire-side through-hole conductive portion covering an inner surface of the wire-side through-hole and electrically connecting the wire bonding pad and the second substrate lower surface electrode to each other.

14. The semiconductor device according to claim 13, wherein the wire-side through-hole overlaps the semiconductor element as viewed in plan.

15. The semiconductor device according to claim 12, wherein the insulating resist film covers a portion of the wire bonding pad.

16. The semiconductor device according to claim 15, wherein the portion of the wire bonding pad which is covered by the insulating resist film overlaps the semiconductor element as viewed in plan.

17. The semiconductor device according to claim 11, wherein the substrate is formed with a die bonding pad, the semiconductor element being bonded to the die bonding pad by the conductive bonding material.

18. The semiconductor device according to claim 17, wherein the insulating resist film is provided at a position avoiding the die bonding pad.

19. The semiconductor device according to claim 17, wherein the insulating resist film covers a periphery of the die bonding

20. The semiconductor device according to claim 17, wherein the die bonding pad includes a raised portion raised upward toward the semiconductor element in a thickness direction, the raised portion being provided in an area enclosed by the barrier.

21. The semiconductor device according to claim 20, wherein the raised portion is smaller in thickness than the insulating resist film.

22. The semiconductor device according to claim 20, wherein the die bonding pad includes a concavely curved edge.

23. The semiconductor device according to claim 11, wherein the insulating resist film includes an oblique portion inclined with respect to a side surface of the substrate, and
the substrate includes a corner positioned outside the oblique portion, the corner being in contact with the sealing resin.

24. The semiconductor device according to claim 11, wherein the substrate includes an element-side through-hole penetrating from a side formed with the insulating resist film toward the first substrate lower surface electrode, and an element-side through-hole conductive portion covering an inner surface of the element-side through-hole and electrically connecting the conductive bonding material and the first substrate lower surface electrode to each other.

25. The semiconductor device according to claim 24, wherein the element-side through-hole overlaps the semiconductor element as viewed in plan.

26. The semiconductor device according to claim 11, wherein the insulating resist film is in a form of a closed enclosure as a whole as viewed in plan.

27. The semiconductor device according to claim 11, wherein the insulating resist film comprises a plurality of regions.

28. The semiconductor device according to claim 1, wherein the semiconductor element is a light-receiving element including a light-receiving surface, the light-receiving surface being provided on a same side as the element upper surface electrode.

29. The semiconductor device according to claim 28, wherein the sealing resin transmits infrared light and blocks visible light.
